(19) United States
(12) Patent Application Publication
(10) Pub. No.: US 2018/0354543 A1
(43) Pub. Date: Dec. 13, 2018

(54) ELECTROSTATIC SENSOR

(71) Applicant: Panasonic Intellecual Property Management Co., Ltd, Osaka (JP)

(72) Inventors: TSUYOSHI NISHIO, Chiba (JP); HIDENORI KITAMURA, Osaka (JP)

(21) Appl. No.: 15/993,524

(22) Filed: May 30, 2018

(30) Foreign Application Priority Data
Jun. 12, 2017 (JP) 2017-115386

(51) Int. Cl. B62D 1/04; G01D 5/24; G01R 27/26; B62D 1/06

(52) U.S. Cl. CPC B62D 1/046; B62D 1/06; G01R 27/2605; G01D 5/24

(57) ABSTRACT

An electrostatic sensor includes: two sensor wires disposed adjacent to each other and covered with a surface layer; and a high dielectric constant material for making a dielectric constant of a first surface layer portion included in the surface layer higher than a dielectric constant of a second surface layer portion other than the first surface layer portion. The first surface layer portion covers peripheral edge regions of the two sensor wires, and the second surface layer portion covers regions other than the peripheral edge regions of the two sensor wires.

### TECHNICAL FIELD

The present invention relates to an electrostatic sensor that detects contact or grip to a steering wheel of a vehicle, for example.

### BACKGROUND ART

Conventionally, a grip sensor to detect grip of a steering wheel of a vehicle has been proposed as an electrostatic sensor (for example, see PTL 1).

### CITATION LIST

### Patent Literature

PTL 1: Unexamined Japanese Patent Publication No. 2002-340712

### SUMMARY OF THE INVENTION

The present invention provides an electrostatic sensor that suppresses occurrence of erroneous detection.

An electrostatic sensor according to one aspect of the present invention includes: a first sensor electrode and a second sensor electrode disposed adjacent to each other and covered with a cover member; and a high dielectric constant material for making a dielectric constant of a first cover portion included in the cover member higher than a dielectric constant of a second cover portion other than the first cover portion. The first cover portion covers a first peripheral edge region including a peripheral edge located at a position close to the second sensor electrode of the first sensor electrode and a second peripheral edge region including a peripheral edge located at a position close to the first sensor electrode of the second sensor electrode. The second cover portion covers a region other than the first peripheral edge region of the first sensor electrode and a region other than the second peripheral edge region of the second sensor electrode.

Note that these comprehensive or specific aspects may be realized by an arbitrary combination of a system and a method.

An electrostatic sensor of the present invention can suppress occurrence of erroneous detection.

### BRIEF DESCRIPTION OF DRAWINGS

FIG. 1 is a view illustrating an example of an interior of a vehicle disposed with an electrostatic sensor according to an exemplary embodiment.

FIG. 2 is a block diagram of the electrostatic sensor according to the exemplary embodiment.

FIG. 3 is a diagram illustrating a detailed configuration example of a portion of the electrostatic sensor according to the exemplary embodiment.

FIG. 4 is a view illustrating an example of a cross section of a rim, to which a sensor group is mounted, according to the exemplary embodiment.

FIG. 5 is a view illustrating an example of a side surface of a resin layer, to which the sensor group is mounted, according to the exemplary embodiment.

FIG. 6 is a view illustrating an example of a surface layer according to the exemplary embodiment.

FIG. 7 is a view illustrating a front surface and cross sections of a rim of a steering wheel according to the exemplary embodiment.

FIG. 8 is a graph illustrating sensitivity distribution and distribution of relative dielectric constants on the rim of the steering wheel according to the exemplary embodiment.

FIG. 9 is a view illustrating a state in which the steering wheel is gripped according to the exemplary embodiment.

FIG. 10 is a view for explaining a relative dielectric constant and an area of a first surface layer portion of the surface layer according to the exemplary embodiment.

FIG. 11 is a view illustrating a state in which a sensor wire is covered with a surface layer according to a first modification of the exemplary embodiment.

FIG. 12 is a view for explaining a thickness and an area of a first surface layer portion of the surface layer according to the first modification of the exemplary embodiment.

FIG. 13 is a diagram illustrating a detailed configuration example of a portion of an electrostatic sensor according to a second modification of the exemplary embodiment.

### DESCRIPTION OF EMBODIMENT

A problem in a conventional grip sensor will be briefly described prior to a description of an exemplary embodiment of the present invention. The grip sensor has, for example, a base material and a sensor wire provided on the base material. Moreover, the base material is wound around a core material of a steering wheel and covered with a buffer material or the like. In this grip sensor, electrostatic capacitance is generated between a vehicle and a sensor wire. When a person's hand comes into contact with the steering wheel, electrostatic capacitance is also generated between the hand and the sensor wire. Therefore, grip of the steering wheel by the person's hand can be detected by observing a change in the electrostatic capacitance generated in the sensor wire.

However, there is a problem in that erroneous detection may occur in this grip sensor as mentioned below.

### (Knowledge Underlying the Present Invention)

The inventors of the present application have found that the following problem arises in the grip sensor described in the section of “BACKGROUND ART”.

For example, the grip sensor has a plurality of sensors, and each sensor has a base material and a sensor wire provided on the base material. The plurality of sensors is wound around, for example, a steering wheel.

Herein, the plurality of sensors is wound around the steering wheel such that the sensors are adjacent to each other. Further, the sensor wire of the sensor is not disposed on a whole surface of the base material, and is disposed only in a region excluding a peripheral edge of the base material. Therefore, a region including a boundary between one sensor and another sensor adjacent to the one sensor, of the plurality of sensors in the steering wheel, becomes an electrodeless region where the sensor wire is not disposed.

For example, when a driver in a vehicle grips a region excluding the electrodeless region of the steering wheel, that is, when the driver grips an electrode region serving as a region where the sensor wire of the sensor is disposed, an output of the sensor is large. As a result, the grip sensor can detect the grip accurately. However, when the driver grips a region including at least the electrodeless region of the steering wheel, an output of the sensor in the electrode region near the electrodeless region is small. As a result, there is a possibility that the grip sensor cannot detect the grip accurately. Therefore, in this grip sensor, detection sensitivity is different depending on a position of the steering wheel, and erroneous detection may occur.

In order to solve this problem, an electrostatic sensor according to one aspect of the present invention includes: a first sensor electrode and a second sensor electrode disposed adjacent to each other and covered with a cover member; and a high dielectric constant material for making a dielectric constant of a first cover portion included in the cover member higher than a dielectric constant of a second cover portion other than the first cover portion. The first cover portion covers a first peripheral edge region including a peripheral edge located at a position close to the second sensor electrode of the first sensor electrode and a second peripheral edge region including a peripheral edge located at a position close to the first sensor electrode of the second sensor electrode. The second cover portion covers a region other than the first peripheral edge region of the first sensor electrode and a region other than the second peripheral edge region of the second sensor electrode. Note that the first sensor electrode and the second sensor electrode may be, for example, electrodes formed in linear shapes, that is, sensor wires. Further, the cover member may be, for example, a surface layer made of leather or resin and covering a core material of a rim of a steering wheel.

With this configuration, the first peripheral edge region of the first sensor electrode and the second peripheral edge region of the second sensor electrode are covered with the first cover portion having the dielectric constant higher than the dielectric constant of the second cover portion covering the region other than those peripheral edge regions. Therefore, detection sensitivity of the first cover portion can be enhanced more than detection sensitivity of the second cover portion. As a result, even when there is an electrodeless region between the first sensor electrode and the second sensor electrode, that is, between the first peripheral edge region and the second peripheral edge region, lowering of the detection sensitivity by the electrodeless region can be suppressed, and detection sensitivity on an outside surface of the cover member can be made uniform. Therefore, occurrence of erroneous detection can be suppressed. Note that the first sensor electrode and the second sensor electrode may be integrally formed.

Further, at least a portion of the high dielectric constant material may be (a) impregnated and disposed in the first cover portion, (b) attached and disposed onto a surface of the first cover portion, or (c) formed of a plurality of particles, and the plurality of particles may be dispersed and disposed on at least one of the surface and an inside of the first cover portion.

With this configuration, the first cover portion having the high dielectric constant and the second cover portion having the low dielectric constant can be easily formed with respect to the cover member.

Further, the cover member is a sheet-shaped base material, and the first sensor electrode and the second sensor electrode may be mounted on a same surface of the base material.

For example, when the base material is disposed in the rim of the steering wheel, if the surface, on which the electrodes are mounted, of the base material is directed to a core material side of the rim, the first sensor electrode and the second sensor electrode are covered with the base material. In other words, the base material is used as the cover member. With this configuration, the first cover portion having the high dielectric constant and the second cover portion having the low dielectric constant can be formed on the base material, and a degree of freedom of designing the electrostatic sensor can be enhanced.

Further, an electrostatic sensor according to another aspect of the present invention includes a first sensor electrode and a second sensor electrode disposed adjacent to each other and covered with a cover member. The first sensor electrode has a first peripheral edge region including a peripheral edge located at a position close to the second sensor electrode and a first center region other than the first peripheral edge region. The second sensor electrode has a second peripheral edge region including a peripheral edge located at a position close to the first sensor electrode and a second center region other than the second peripheral edge region. The first peripheral edge region and the second peripheral edge region are closer to an exposed outside surface of the cover member than the first center region and the second center region are. For example, the cover member has a first cover portion to cover the first peripheral edge region and the second peripheral edge region and a second cover portion to cover the first center region and the second center region. The first cover portion is thinner than the second cover portion.

With this configuration, since the first peripheral edge region of the first sensor electrode and the second peripheral edge region of the second sensor electrode are closer to the outside surface of the cover member than the other regions are, detection sensitivity at the portion covering the first peripheral edge region and the second peripheral edge region of the cover member can be made higher than detection sensitivity at the portion covering the other regions. As a result, even when there is an electrodeless region between the first sensor electrode and the second sensor electrode, that is, between the first peripheral edge region and the second peripheral edge region, lowering of the detection sensitivity by the electrodeless region can be suppressed, and detection sensitivity on the outside surface of the cover member can be made uniform. Therefore, occurrence of erroneous detection can be suppressed. Note that the first sensor electrode and the second sensor electrode may be integrally formed.

Further, a width of a region including the first peripheral edge region and the second peripheral edge region in a direction in which the first sensor electrode and the second sensor electrode are disposed adjacent to each other may be smaller than a width of a detection object of the electrostatic sensor.

With this configuration, even when there is an electrodeless region between the first sensor electrode and the second sensor electrode, that is, between the first peripheral edge region and the second peripheral edge region, the width of the detection object is larger than the width of the region including the first peripheral edge region and the second peripheral edge region. Therefore, when the detection object touches a position corresponding to the electrodeless region on the outside surface of the cover member, the detection object touches not only the position corresponding to the electrodeless region, but also a position corresponding to the first peripheral edge region or the second peripheral edge region. In other words, the detection object touches not only the position corresponding to the electrodeless region and having the low detection sensitivity, but also the position corresponding to the first peripheral edge region or the second peripheral edge region and having the high detection sensitivity. Therefore, even if the detection sensitivity at the position corresponding to the electrodeless region is lower than the detection sensitivity at positions corresponding to the center regions of the first sensor electrode and the second sensor electrode, the low detection sensitivity can be compensated by the high detection sensitivity at the position corresponding to the first peripheral edge region or the second peripheral edge region. In other words, the low detection sensitivity and the high detection sensitivity can be canceled by each other. With this configuration, the detection sensitivity on the outside surface of the cover member can be made more uniform.

Further, the electrostatic sensor may be a grip sensor to detect grip of a mounting object, to which the electrostatic sensor is mounted.

With this configuration, occurrence of erroneous detection with respect to the grip of the mounting object, for example, a rim of a steering wheel can be suppressed.

Hereinafter, an exemplary embodiment will specifically be described with reference to the drawings.

Note that the following exemplary embodiment provides a comprehensive or specific example of the present invention. Numerical values, shapes, materials, components, arrangement positions and connection modes of the components, steps, and order of the steps, for example, illustrated in the following exemplary embodiment are examples, and therefore are not intended to limit the present invention. Furthermore, among components in the following exemplary embodiment, components not recited in the independent claim indicating the broadest concept are described as optional components.

It should be noted that each of the diagrams is schematic, and is not necessarily strictly accurate. Further, in each diagram, the same components are denoted by the same reference marks.

### EXEMPLARY EMBODIMENT

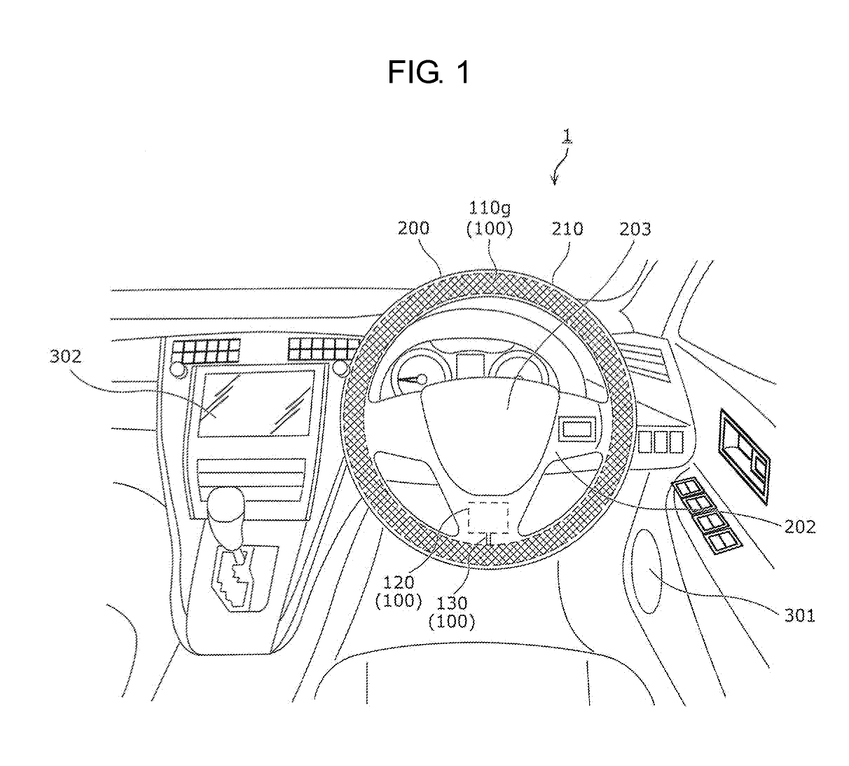

FIG. 1 is a view illustrating an example of an interior of a vehicle disposed with an electrostatic sensor according to an exemplary embodiment.

Vehicle 1 includes steering wheel 200, speaker 301, and display device 302, such as a liquid crystal display. For example, speaker 301 and display device 302 are configured as attention calling devices.

Steering wheel 200 is a unit for steering vehicle 1. Steering wheel 200 has rim 210 having a ring shape, substantially T-shaped spoke 202 integrally formed on an inner peripheral surface of rim 210, and horn switch cover 203 to cover a horn switch (not illustrated) disposed in a center of spoke 202.

Electrostatic sensor 100 is an electrostatic capacitance type proximity sensor, and is a sensor that detects information of an occupant in vehicle 1 having steering wheel 200. In the present exemplary embodiment, electrostatic sensor 100 detects contact or grip to rim 210 of steering wheel 200 by a hand of a driver, who is an occupant, as information of the occupant. As illustrated in FIG. 1, this electrostatic sensor 100 is disposed in steering wheel 200 of vehicle 1. Specifically, electrostatic sensor 100 includes sensor group 110g formed with a plurality of sensors, control circuit 120, and harness 130.

Sensor group 110g is embedded in rim 210 of steering wheel 200. In each sensor included in sensor group 110g, electrostatic electric capacitance to be measured is changed according to whether or not the driver in vehicle 1 grips rim 210 of steering wheel 200 or according to whether or not the driver touches rim 210.

Harness 130 electrically connects each sensor of sensor group 110g and control circuit 120.

Control circuit 120 is, for example, embedded in spoke 202, and detects contact or grip based on an output signal from each sensor of sensor group 110g. Specifically, control circuit 120 measures, with respect to each sensor, electrostatic capacitance of the sensor or a value according to the electrostatic capacitance (an amount of change), and detects grip or the like of rim 210 by a hand of the driver based on the value. Moreover, when the grip is not detected even though vehicle 1 is driven, control circuit 120 causes the attention calling devices to call attention to the driver. For example, speaker 301 serving as the attention calling device calls attention to the driver by warning tone or voice. Display device 302 displays an attention calling message that promotes the driver to firmly hold steering wheel 200. With this configuration, traffic accidents can be reduced.

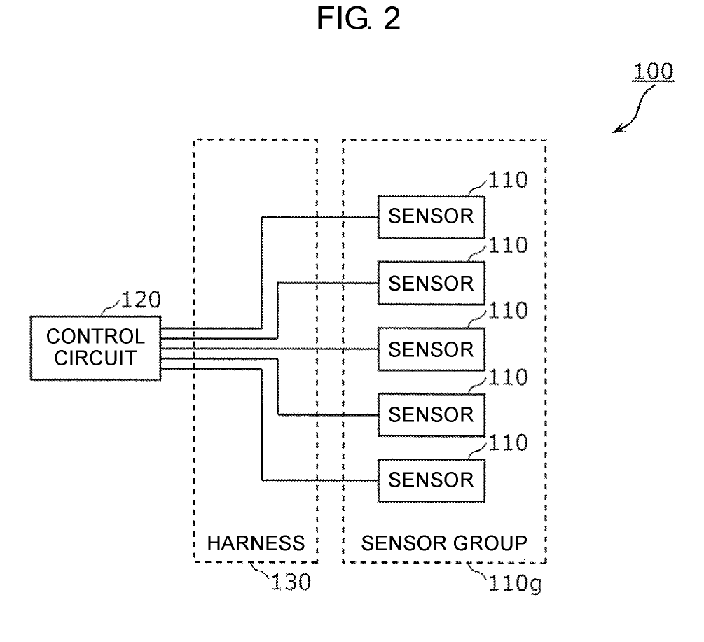

FIG. 2 is a block diagram illustrating a configuration example of electrostatic sensor 100 according to the present exemplary embodiment.

Electrostatic sensor 100 includes sensor group 110g formed with five sensors 110, control circuit 120, and harness 130. Note that sensor group 110g is formed with five sensors 110 in the present exemplary embodiment. However, a number of sensors 110 is not limited to five, and may be four or less, or six or more.

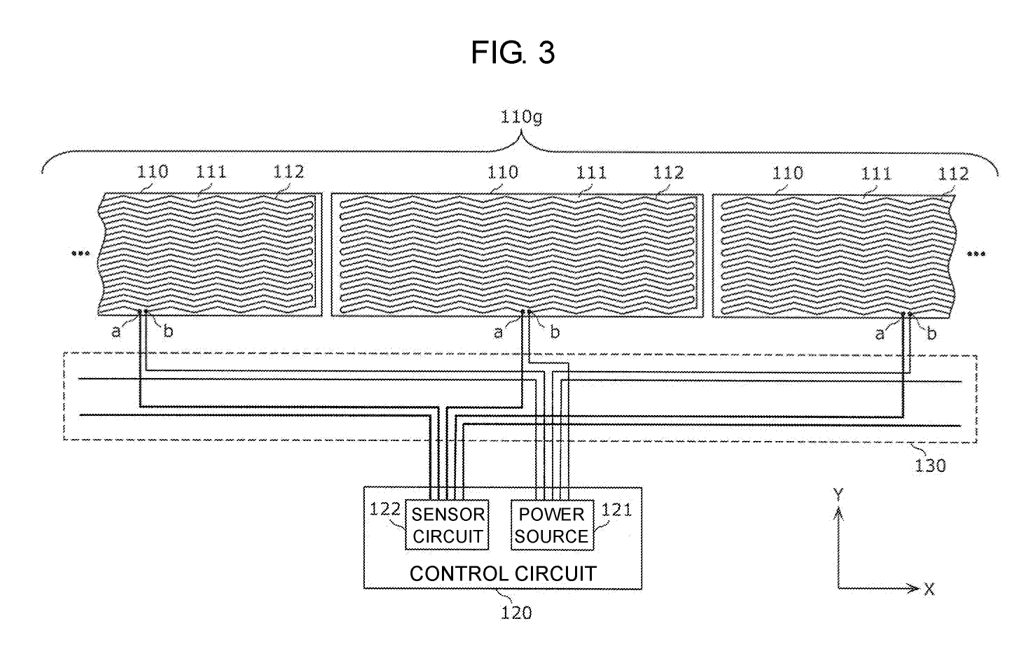

FIG. 3 is a diagram illustrating a detailed configuration example of a portion of electrostatic sensor 100 according to the present exemplary embodiment.

Each of five sensors 110 includes base material 111 and sensor wire 112 serving as a sensor electrode. Note that five sensors 110 have a practically same configuration in the present exemplary embodiment.

Base material 111 is made of, for example, non-woven fabric, is formed long, and holds sensor wire 112. This base material 111 is mounted to rim 210 of steering wheel 200. Note that, in the present exemplary embodiment, a longitudinal direction of base material 111 is referred to as an X-axis direction, and a direction perpendicular to the X-axis direction on a surface parallel to base material 111 is referred to as a Y-axis direction. Further, one end side (a lower end side in FIG. 3) of base material 111 in the Y-axis direction is referred to as a negative side, and another end side (an upper end side in FIG. 3) of base material 111 in the Y-axis direction is referred to as a positive side. Similarly, one end side (a left end side in FIG. 3) of base material 111 in the X-axis direction is referred to as a negative side, and another end side (a right end side in FIG. 3) of base material 111 in the X-axis direction is referred to as a positive side.

Sensor wire 112 is made of a conductive wire, and one end (that is, end-a) and another end (that is, end-b) of sensor wire 112 are connected to control circuit 120 via harness 130. Sensor wire 112 herein is disposed in a zigzag shape in base material 111. Specifically, sensor wire 112 is a metal wire (for example, a copper wire), and is sewn on a surface of base material 111 with a thread (not illustrated) so as to form a zigzag-shaped pattern.

Sensor wire 112 according to the present exemplary embodiment is sewn on the surface of base material 111 with the thread (not illustrated). However, sensor wire 112 may be fixed to base material 111 by thermocompression bonding or the like. Furthermore, sensor wire 112 may have a planar structure formed with a conductor or a resistor. Further, sensor wire 112 is made of the conductive wire in the present exemplary embodiment. However, any form may be used as long as a member has conductivity. In other words, electrostatic sensor 100 according to the present exemplary embodiment includes sensor wire 112 as the sensor electrode. However, the sensor electrode may not be formed in a linear shape like sensor wire 112.

Control circuit 120 includes power source circuit 121 and sensor circuit 122. Note that end-a serving as the one end of sensor wire 112 is connected to sensor circuit 122 and end-b serving as the other end of sensor wire 112 is connected to power source circuit 121.

Power source circuit 121 is electrically connected to end-b of sensor wire 112 of each of five sensors 110 via harness 130. Further, power source circuit 121 heats sensor wire 112 by causing a current to flow in sensor wire 112. With this configuration, rim 210 of steering wheel 200 can be warmed. In order to cause the current to flow from power source circuit 121 to sensor wire 112, in control circuit 120, a middle of a wiring line from end-a of sensor wire 112 to sensor circuit 122 is connected to ground via an inductor (not illustrated).

Sensor circuit 122 detects contact or grip of steering wheel 200 by using sensor wire 112 of each of five sensors 110. In other words, sensor circuit 122 causes an alternating current to flow in sensor wire 112 via harness 130. Then, sensor circuit 122 detects a change in electrostatic capacitance of sensor wire 112 based on a current value of the current flowing in sensor wire 112.

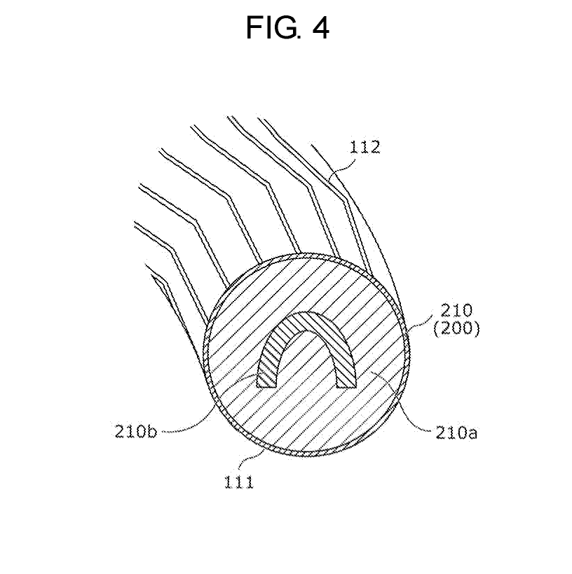

FIG. 4 is a view illustrating an example of a cross section of rim 210, to which sensor group 110g is mounted. Note that a surface layer disposed on an outermost side of rim 210 is omitted in the cross section illustrated in FIG. 4.

Rim 210 has a core material. The core material of rim 210 is formed with metal cored bar 210b, which is an annular core, and resin layer 210a covering cored bar 210b and made of urethane resin or the like.

As illustrated in FIG. 3, base material 111, on which sensor wire 112 is sewn, is wound around resin layer 210a such that a surface on a side opposite to sensor wire 112 is directed to a side of resin layer 210a. Note that a surface on a side of sensor wire 112 of base material 111 wound in this way is covered with a surface layer (not illustrated) made of leather, timber, resin, or the like. Further, five sensors 110 are disposed in a row along a circumferential direction of rim 210 in the present exemplary embodiment. Note that, in the present exemplary embodiment, base material 111 is wound around resin layer 210a such that the surface on the side opposite to sensor wire 112 is directed to the side of resin layer 210a. However, base material 111 may be wound around resin layer 210a such that the surface on the side of sensor wire 112 of base material 111 is directed to the side of resin layer 210a.

Electrostatic capacitance is formed between sensor wire 112 disposed in rim 210 and cored bar 210b. Herein, when a part disposed with sensor wire 112 of rim 210 is gripped by a driver's hand, electrostatic capacitance is also formed between sensor wire 112 and the hand. Therefore, sensor circuit 122 of control circuit 120 can detect grip of rim 210 caused by the hand according to an absolute value or an amount of change of the electrostatic capacitance. Note that the present invention is not limited to a configuration in which the electrostatic capacitance is formed between sensor wire 112 and cored bar 210b. For example, it is possible to have a configuration in which a ground layer made of a conductive sheet or the like is provided between sensor wire 112 and cored bar 210b and electrostatic capacitance is formed between sensor wire 112 and the ground layer.

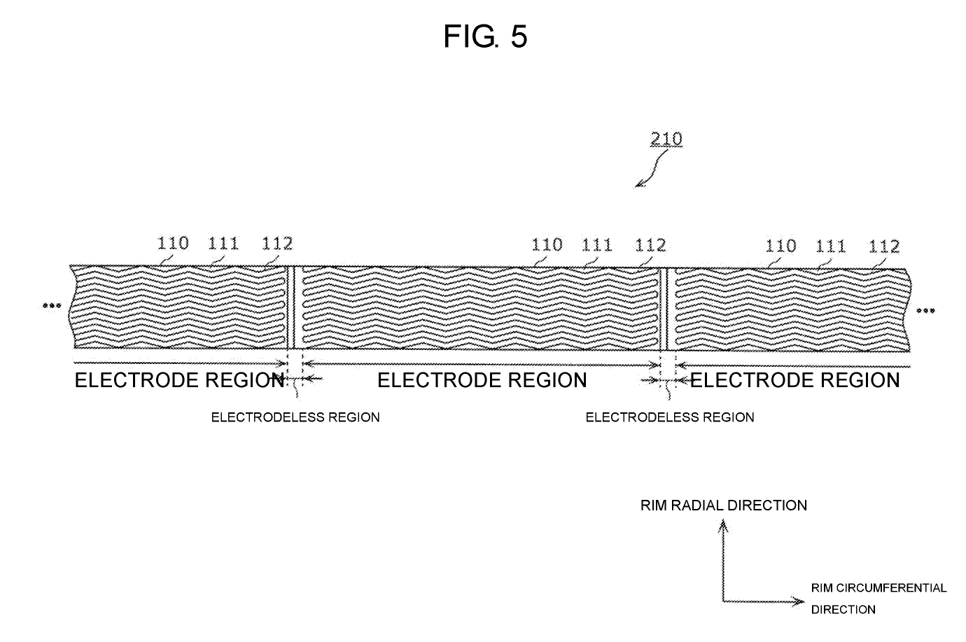

FIG. 5 is a view illustrating an example of a side surface of resin layer 210a, to which sensor group 110g is mounted, according to the exemplary embodiment. Note that, as with FIG. 4, a surface layer is omitted on the side surface illustrated in FIG. 5.

Sensors 110 included in sensor group 110g are disposed on resin layer 210a so as to be adjacent to each other. At this time, ends of base materials 111 of two sensors 110 adjacent to each other may abut on each other. Herein, sensor wire 112 is not sewn to a peripheral edge of base material 111 in each sensor 110. In other words, an electrode region serving as a region, on which sensor wire 112 is sewn, is not provided at the peripheral edge of base material 111. As a result, even when sensors 110 are disposed on resin layer 210a such that the ends of base materials 111 are abut on each other as described above, the electrode regions are disposed discontinuously, as illustrated in FIG. 5. In other words, a region where the electrode region does not exist is formed in rim 210. For example, when a surface layer covers an electrodeless region serving as the region where the electrode region does not exist in a same manner as the electrode layer, detection sensitivity may become different depending on the position of rim 210.

Accordingly, in the present exemplary embodiment, resin layer 210a, to which sensor group 110g is mounted, is covered with a surface layer having a first surface layer portion and a second surface layer portion whose dielectric constants are different from each other.

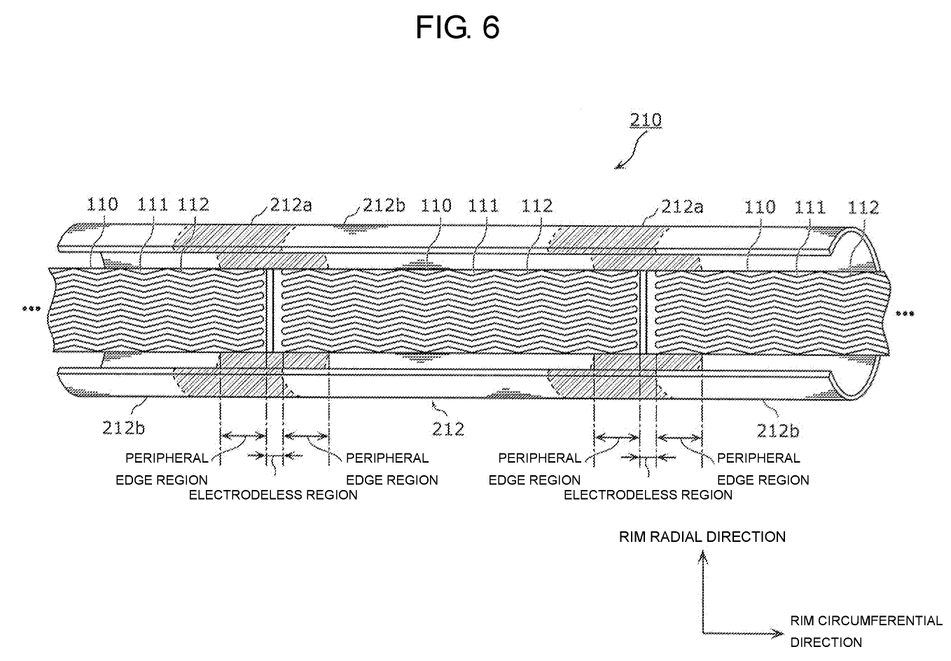

FIG. 6 is a view illustrating an example of a surface layer according to the present exemplary embodiment.

In the present exemplary embodiment, resin layer 210a, to which sensor group 110g is mounted, is covered with surface layer 212 made of leather, resin, or the like. This surface layer 212 has first surface layer portion 212a and second surface layer portion 212b, and a dielectric constant of first surface layer portion 212a is higher than a dielectric constant of second surface layer portion 212b.

Such first surface layer portion 212a covers peripheral edge regions of two sensor wires 112 adjacent to each other. Further, second surface layer portion 212b covers a region other than the peripheral edge regions of sensor wires 112. Note that the peripheral edge region of each of two sensor wires 112 adjacent to each other is a region including a peripheral edge on a side of adjacent other sensor wire 112 of the electrode region serving as the region, on which sensor wire 112 is sewn, of base material 111. The peripheral edge regions of these two sensor wires 112 are disposed so as to sandwich the above-described electrodeless region.

Note that surface layer 212 having first surface layer portion 212a and second surface layer portion 212b according to the present exemplary embodiment is an example of a cover member having a first cover portion and a second cover portion.

In other words, electrostatic sensor 100 according to the present exemplary embodiment includes: at least two sensor wires 112 disposed adjacent to each other and covered with surface layer 212; and a high dielectric constant material for making the dielectric constant of first surface layer portion 212a included in surface layer 212 higher than the dielectric constant of second surface layer portion 212b other than first surface layer portion 212a. This high dielectric constant material is, for example, polysulfide rubber. The dielectric constant of first surface layer portion 212a is made higher than the dielectric constant of second surface layer portion 212b by this high dielectric constant material. Note that a relative dielectric constant of the polysulfide rubber serving as an example of the high dielectric constant material is about six, and a relative dielectric constant of the leather serving as an example of second surface layer portion 212b is about two. In this case, the dielectric constant of first surface layer portion 212a is about three times the dielectric constant of second surface layer portion 212b.

Such first surface layer portion 212a covers the peripheral edge region including the peripheral edge on a side of other sensor wire 112 of one sensor wire 112 of above-described two sensor wires 112 and the peripheral edge region including the peripheral edge on one sensor wire 112 side of other sensor wire 112. Second surface layer portion 212b covers the region other than the peripheral edge region of one sensor wire 112 and the region other than the peripheral edge region of other sensor wire 112.

Furthermore, a width of a region including the peripheral edge region of one sensor wire 112 and the peripheral edge region of other sensor wire 112 in a direction in which one sensor wire 112 and other sensor wire 112 are disposed adjacent to each other is smaller than a width of a detection object of electrostatic sensor 100. Note that the above-described direction in which one sensor wire 112 and other sensor wire 112 are disposed adjacent to each other is the circumferential direction of rim 210, and that the above-described width of the region corresponds to a width of first surface layer portion 212a.

Further, at least a portion of the high dielectric constant material is (a) impregnated and disposed in first surface layer portion 212a, (b) attached and disposed onto a surface of first surface layer portion 212a, or (c) formed of a plurality of particles, and the plurality of particles is dispersed and disposed on at least one of the surface and an inside of first surface layer portion 212a. Note that the surface of first surface layer portion 212a may be an exposed outside surface or an unexposed inside surface of first surface layer portion 212a. Further, a portion of the high dielectric constant material may be impregnated in first surface layer portion 212a, another portion may be attached onto the surface of first surface layer portion 212a, and still another portion may be formed of a plurality of particles, and the plurality of particles may be dispersed and disposed on at least one of the surface and the inside of first surface layer portion 212a. For example, the plurality of dispersed and disposed particles may be barium titanate powder having a relative dielectric constant of 1200.

With this configuration, first surface layer portion 212a having the high dielectric constant and second surface layer portion 212b having the low dielectric constant can be easily formed with respect to surface layer 212 serving as the cover member.

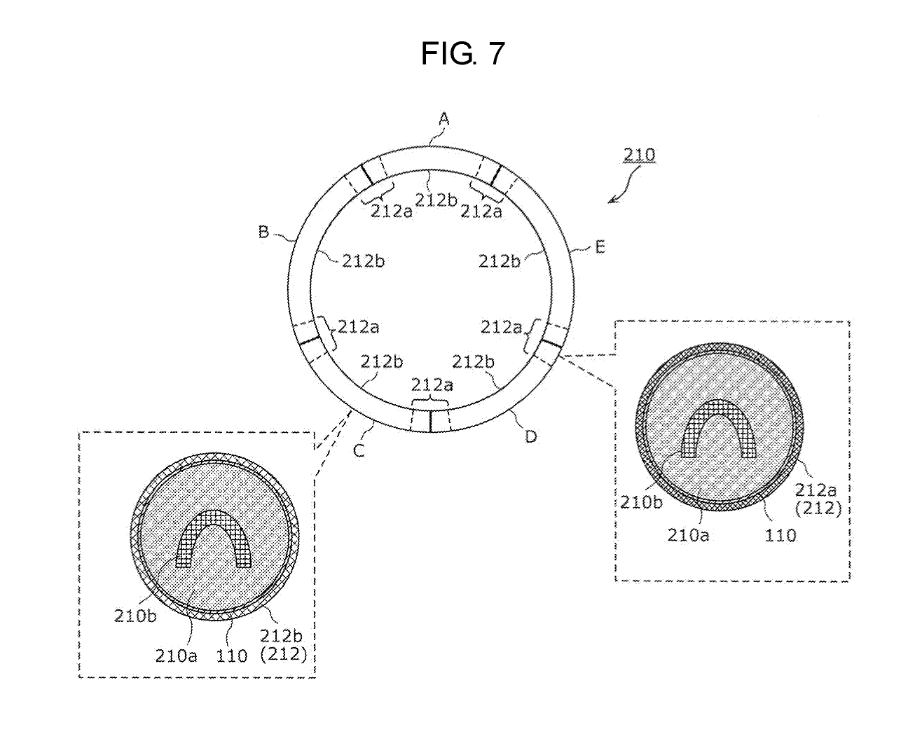

FIG. 7 is a view illustrating a front surface and cross sections of rim 210 of steering wheel 200 according to the present exemplary embodiment.

As illustrated in FIG. 7, rim 210 of steering wheel 200 is formed with five parts A to E, to each of which sensor 110 is mounted. In steering wheel 200 in a neutral state where a steering angle is 0 degrees, part A is on an upper side, part B is on an upper left side, part C is on a lower left side, part D is on a lower right side, and part E is on an upper right side. Note that when the steering angle of steering wheel 200 is 0 degrees, vehicle 1 goes straight. Further, parts A to E each have a same configuration.

In the present exemplary embodiment, first surface layer portion 212a having the high dielectric constant of surface layer 212 of rim 210 is disposed so as to extend over boundaries of parts A to E, and second surface layer portion 212b having the low dielectric constant is disposed in regions other than both ends of parts A to E.

For example, as illustrated in FIG. 7, in a center of part C, second surface layer portion 212b having the low dielectric constant of surface layer 212 covers a portion of sensor 110 disposed in part C. Specifically, second surface layer portion 212b covers a region other than the peripheral edge regions of sensor wire 112 of sensor 110. Further, in the boundary between part D and part E, first surface layer portion 212a having the high dielectric constant of surface layer 212 covers a portion on a side of part E of sensor 110 disposed in part D and a portion on a side of part D of sensor 110 disposed in part E. Specifically, first surface layer portion 212a covers the peripheral edge region on the side of part E of sensor wire 112 in part D and the peripheral edge region on the side of part D of sensor wire 112 in part E. Note that, as illustrated in FIG. 6, first surface layer portion 212a covers not only the peripheral edge regions in two sensor wires 112, but also the electrodeless region sandwiched by these peripheral edge regions.

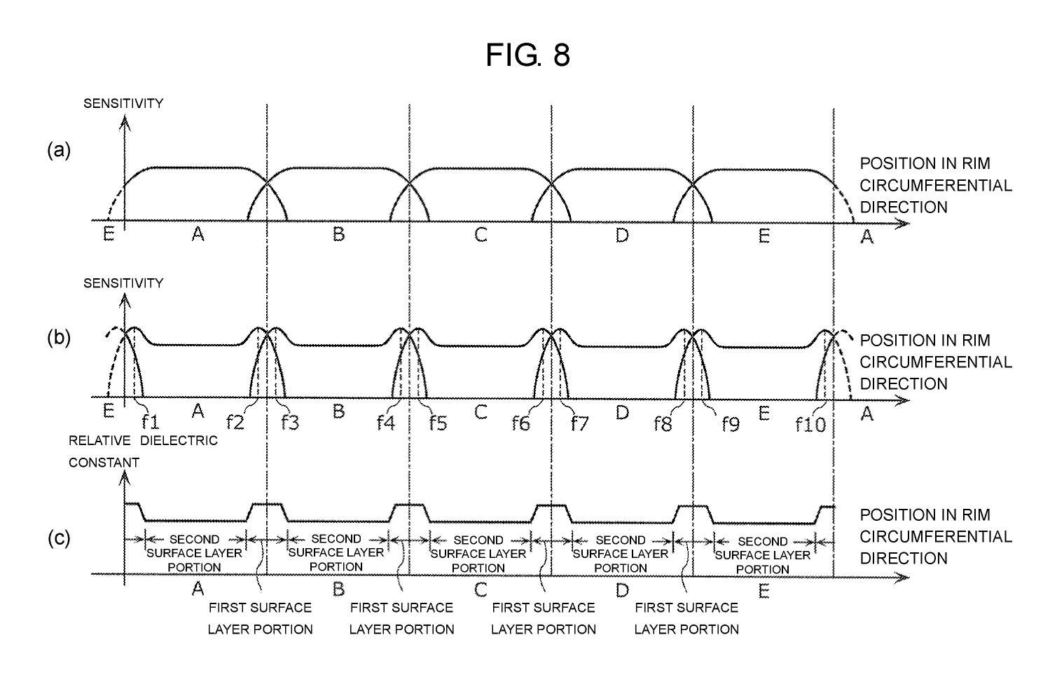

FIG. 8 is a graph illustrating sensitivity distribution and distribution of relative dielectric constants on rim 210 of steering wheel 200 according to the present exemplary embodiment. Note that part (a) of FIG. 8 is a comparative example for comparing with sensitivity distribution of electrostatic sensor 100 according to the present exemplary embodiment, and illustrates sensitivity distribution of an electrostatic sensor using a surface layer having a uniform dielectric constant. Part (b) of FIG. 8 illustrates sensitivity distribution of electrostatic sensor 100 according to the present exemplary embodiment. Part (c) of FIG. 8 illustrates distribution of relative dielectric constants of surface layer 212 according to the present exemplary embodiment.

As illustrated in part (a) of FIG. 8, when the surface layer having the uniform dielectric constant (or relative dielectric constant) is used, sensitivity lowers in the boundaries of parts A to E of rim 210. For example, sensitivity in the boundary between part A and part B is lower than sensitivity in a center of part A. On the other hand, in the present exemplary embodiment, as illustrated in part (c) of FIG. 8, dielectric constants of portions corresponding to the vicinity of boundaries of parts A to E (that is, first surface layer portions 212a) of surface layer 212 are higher than dielectric constants of the other portions (that is, second surface layer portions 212b). Therefore, as illustrated in part (b) of FIG. 8, detection sensitivity at positions f1 to f10 near the boundaries of parts A to E of rim 210 (that is, positions on both end sides of first surface layer portions 212a) can be improved more than detection sensitivity near the centers of parts A to E. Note that positions f1 to f10 are positions corresponding to the electrode regions, that is, the peripheral edge regions of sensor wires 112, and first surface layer portions 212a having the high dielectric constants of surface layer 212. Therefore, lowering of detection sensitivity caused by the electrodeless regions in the boundaries of parts A to E of rim 210 can be suppressed.

In this way, in the present exemplary embodiment, the peripheral edge region of one sensor wire 112 and the peripheral edge region of other sensor wire 112 are covered with first surface layer portion 212a having the dielectric constant higher than the dielectric constant of second surface layer portion 212b that covers the other regions. Therefore, the detection sensitivity of first surface layer portion 212a can be enhanced more than the detection sensitivity of second surface layer portion 212b. As a result, even when there is an electrodeless region between the peripheral edge region of one sensor wire 112 and the peripheral edge region of other sensor wire 112, lowering of the detection sensitivity caused by the electrodeless region can be suppressed, and the detection sensitivity on the outside surface of surface layer 212 can be made uniform. Therefore, occurrence of erroneous detection can be suppressed.

Further, in the present exemplary embodiment, a width of first surface layer portion 212a is smaller than a width of a detection object, such as a driver's hand or finger. In other words, even when there is an electrodeless region between two sensor wires 112 adjacent to each other, the width of the detection object is larger than a width of a region including the electrodeless region and the peripheral edge regions of two sensor wires 112. Therefore, when the detection object touches a position corresponding to the electrodeless region on the outside surface of surface layer 212, the detection object touches not only the position corresponding to the electrodeless region on that surface, but also positions corresponding to the peripheral edge regions of these sensor wires 112. In other words, the detection object touches not only the position corresponding to the electrodeless region and having the low detection sensitivity located in the boundary of each of parts A to E of rim 210, but also the positions corresponding to the peripheral edge regions of sensor wires 112 and having the high detection sensitivity. Therefore, even if the detection sensitivity in the boundary of each of parts A to E (a dashed line illustrated in FIG. 8) is lower than the detection sensitivity near the center of each of parts A to E, the low detection sensitivity can be compensated by the high detection sensitivity at the positions corresponding to the peripheral edge regions of sensor wires 112. In other words, the low detection sensitivity and the high detection sensitivity can be canceled by each other. With this configuration, the detection sensitivity on the outside surface of surface layer 212 can be made more uniform.

Therefore, in electrostatic sensor 100 according to the present exemplary embodiment, occurrence of erroneous detection to grip of rim 210 of steering wheel 200 serving as a mounting object can be suppressed.

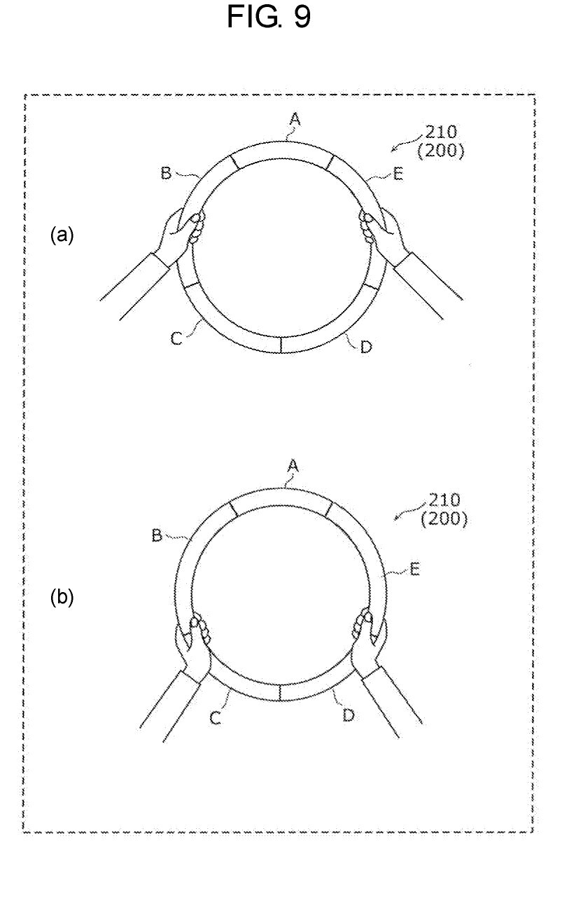

FIG. 9 is a view illustrating a state in which steering wheel 200 is gripped. Note that steering wheel 200 is simplified and only an external appearance of rim 210 is illustrated in FIG. 9.

For example, as illustrated in part (a) of FIG. 9, a driver's left hand grips part B of rim 210, and the driver's right hand grips part E of rim 210. At this time, sensor wire 112 mounted to part B outputs a signal according to the grip by the driver's left hand, and sensor wire 112 mounted to part E outputs a signal according to the grip by the driver's right hand.

Herein, as illustrated in part (b) of FIG. 9, the driver's left hand grips the boundary between part B and part C of rim 210, and the driver's right hand grips the boundary between part D and part E of rim 210. In other words, the left hand extends over part B and part C, and the right hand extends over part D and part E. At this time, in the present exemplary embodiment, as illustrated in part (b) of FIG. 8, averaged detection sensitivity around the boundary between part B and part C is not smaller than and is practically same as detection sensitivity near the center of part B. Similarly, averaged detection sensitivity around the boundary between part D and part E is not smaller than and is practically same as detection sensitivity near the center of part E. Therefore, even when the driver changes gripping parts of rim 210 of steering wheel 200 from the parts illustrated in part (a) of FIG. 9 to the parts illustrated in part (b) of FIG. 9, electrostatic sensor 100 according to the present exemplary embodiment can appropriately detect the grip.

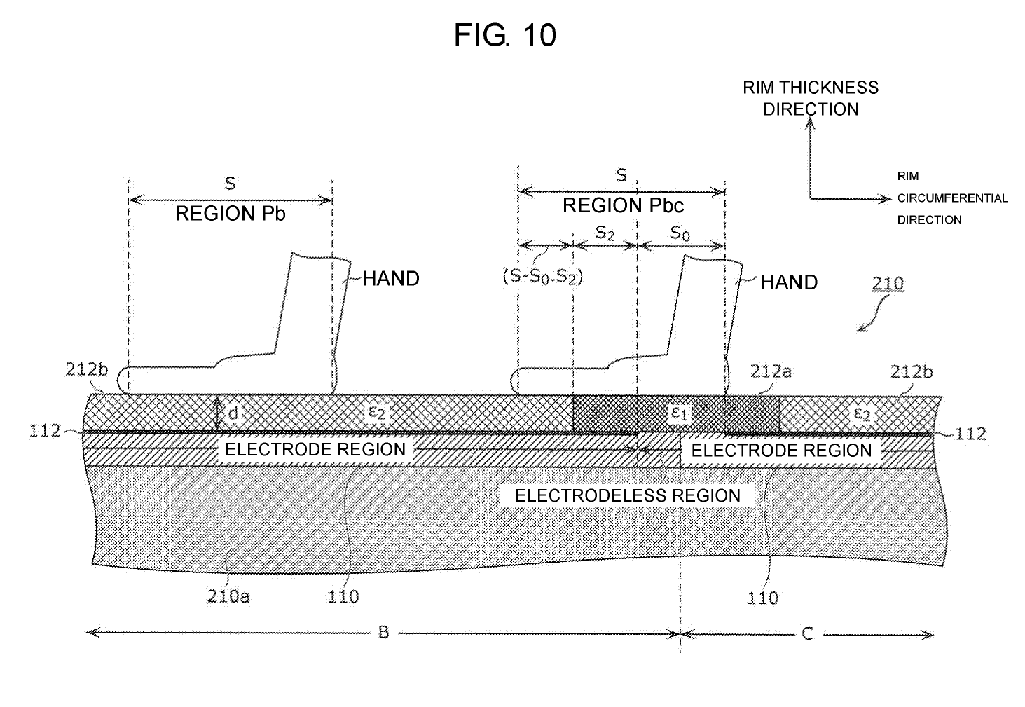

FIG. 10 is a view for explaining a relative dielectric constant and an area of first surface layer portion 212a of surface layer 212. Note that FIG. 10 is a partial sectional view of rim 210 in a plane along a circumferential direction and a radial direction of rim 210.

For example, when a driver's hand touches a portion corresponding to the electrodeless region of the surface of rim 210, it is assumed that detection sensitivity becomes low. Furthermore, when the driver's hand touches a range from one end to another end in the circumferential direction of rim 210 of that portion, it is assumed that detection sensitivity becomes the lowest.

Therefore, as illustrated in FIG. 10, even when the driver's hand touches region Pb near the center of part B located on the surface of rim 210, or even when the driver's hand touches region Pbc including the boundary between part B and part C, it is desirable that the detection sensitivity be substantially equalized by adjusting a relative dielectric constant or the like. Alternatively, it is desirable that the detection sensitivity in region Pbc be higher than the detection sensitivity in region Pb.

Herein, region Pb is a region touched by a hand in second surface layer portion 212b of surface layer 212. Region Pbc is a region touched by a hand over first surface layer portion 212a and second surface layer portion 212b of surface layer 212. Further, a portion corresponding to region Pbc of first surface layer portion 212a covers a portion of the electrodeless region and a portion of an electrode region of sensor 110 in part B. Note that this portion of the electrode region of sensor 110 is a peripheral edge region of sensor wire 112.

Hereinafter, the relative dielectric constant and the area of first surface layer portion 212a will be explained in such a manner that the detection sensitivity in region Pbc is higher than or equal to the detection sensitivity in region Pb. It is assumed herein that a parallel plate capacitor is formed between the driver's hand and sensor wire 112 of sensor 110. Further, it is assumed that the electrodeless region does not contribute to electrostatic capacitance of the capacitor.

When the hand touches region Pb, electrostatic capacitance Cb between the hand and sensor 110 in part B can be expressed by following (formula 1).

Cb=ε₀×ε₂×S/d (formula 1)

Note that ε₀ is a dielectric constant in a vacuum, and ε₂ is a relative dielectric constant of second surface layer portion 212b. Further, S is an area of rim 210 touched by the driver's hand, and is each area of region Pb and region Pbc. d is a thickness of surface layer 212.

On the other hand, when the hand touches region Pbc, electrostatic capacitance Cbc between the hand and sensor 110 in part B can be expressed by following (formula 2).

Cbc=ε₀×ε₁×S₂/d+ε₀×ε₂×(S−S₀−S₂)/d (formula 2)

Note that ε₁ is a relative dielectric constant of first surface layer portion 212a. S₀ is an area of the region corresponding to the electrodeless region of region Pbc. S₂ is an area of a region located in first surface layer portion 212a and corresponding to the electrode region of region Pbc.

In the present exemplary embodiment, it is desirable that the detection sensitivity in region Pbc be higher than the detection sensitivity in region Pb, as described above. In other words, Cbc≥Cb is preferably satisfied. As a result, a relation in (formula 4) is derived by following (formula 3).

{ε₀×ε₁×S₂/d+ε₀×ε₂×(S−S₀−S₂)/d}≥{ε₀×ε₂×S/d} (formula 3)

S₀≤S₂×(ε₁/ε₂−1) (formula 4)

In other words, when relative dielectric constant ε₂ and area S₀ are determined, relative dielectric constant ε₁ and area S₂ may be determined based on the above-described (formula 4). Further, the area and the width, that is, a circumferential width of rim 210, of first surface layer portion 212a can be derived from determined area S₂ and area S₀.

### (First Modification)

In the above-described exemplary embodiment, in order to equalize the detection sensitivity at each position in rim 210, the dielectric constants of first surface layer portion 212a and second surface layer portion 212b of surface layer 212 are made different. In electrostatic sensor 100 according to the present modification, in order to equalize the detection sensitivity, a distance from sensor wire 112 to an outside surface of first surface layer portion 212a and a distance from sensor wire 112 to an outside surface of second surface layer portion 212b are made different.

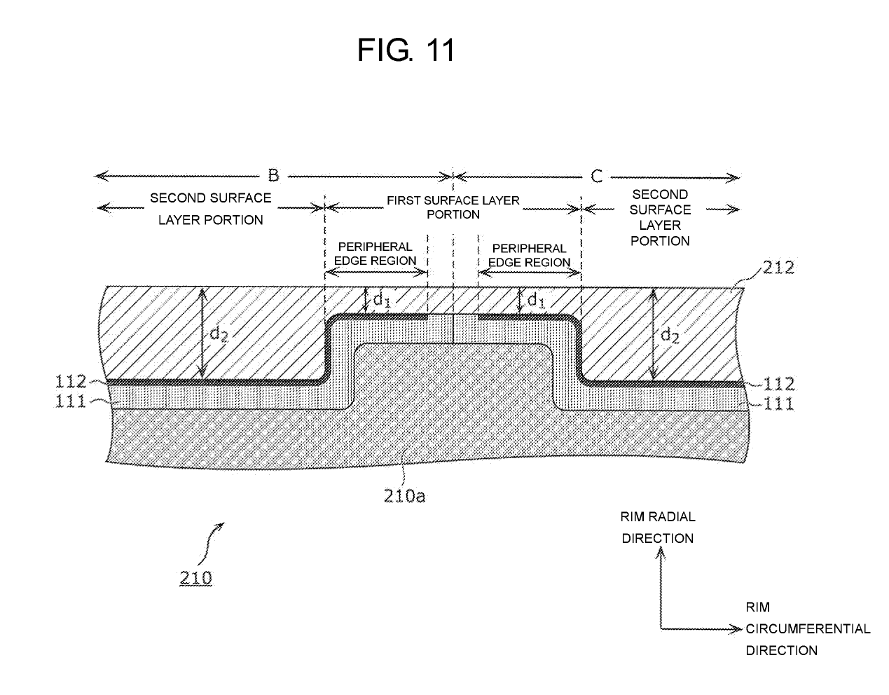

FIG. 11 is a view illustrating a state in which sensor wire 112 is covered with surface layer 212 according to the present modification. Note that, as with FIG. 10, FIG. 11 is a partial sectional view of rim 210 in a plane along a circumferential direction and a radial direction of rim 210.

In the present modification, each of five sensors 110 included in sensor group 110g is disposed in rim 210 such that a peripheral edge region of sensor wire 112 is closer to the outside surface of surface layer 212 than a region other than the peripheral edge region is. In other words, the peripheral edge region of each of five sensors 110 is located shallower than the other region.

Specifically, first surface layer portion 212a of surface layer 212 covers a peripheral edge region including a peripheral edge on a side of part C of sensor wire 112 in part B and a peripheral edge region including a peripheral edge on a side of part B of sensor wire 112 in part C. Further, second surface layer portion 212b of surface layer 212 covers a region other than the peripheral edge region of sensor wire 112 in part B and a region other than the peripheral edge region of sensor wire 112 in part C. Moreover, distance d1 from sensor wire 112 in each of parts B and C to the outside surface of first surface layer portion 212a is shorter than distance d2 from sensor wire 112 to the outside surface of second surface layer portion 212b.

In this way, electrostatic sensor 100 according to the present modification includes two sensor wires 112 disposed adjacent to each other and covered with surface layer 212 serving as an example of a cover member. One sensor wire 112 of two sensor wires 112 has the peripheral edge region including the peripheral edge on a side of other sensor wire 112 and a center region other than the peripheral edge region. Similarly, other sensor wire 112 also has the peripheral edge region including the peripheral edge on a side of one sensor wire 112 and a center region other than the peripheral edge region. Moreover, the peripheral edge regions of these two sensor wires 112 are closer to the outside surface of surface layer 212 than the center regions are. In other words, in the present modification, surface layer 212 has first surface layer portion 212a covering the peripheral edge regions of two sensor wires 112 and second surface layer portion 212b covering the center region of each of two sensor wires 112. First surface layer portion 212a is thinner than second surface layer portion 212b.

With this configuration, since the peripheral edge regions of two sensor wires 112 are closer to the outside surface of surface layer 212 than the other regions are, detection sensitivity at the portion covering the peripheral edge regions of surface layer 212 can be made higher than detection sensitivity at the portion covering the other regions. As a result, even when there is an electrodeless region between one sensor wire 112 and other sensor wire 112, that is, between the peripheral edge region of one sensor wire 112 and the peripheral edge region of other sensor wire 112, lowering of the detection sensitivity caused by the electrodeless region can be suppressed. With this configuration, the detection sensitivity on the outside surface of surface layer 212 can be made uniform. Therefore, occurrence of erroneous detection can be suppressed in a same manner as the above-described exemplary embodiment.

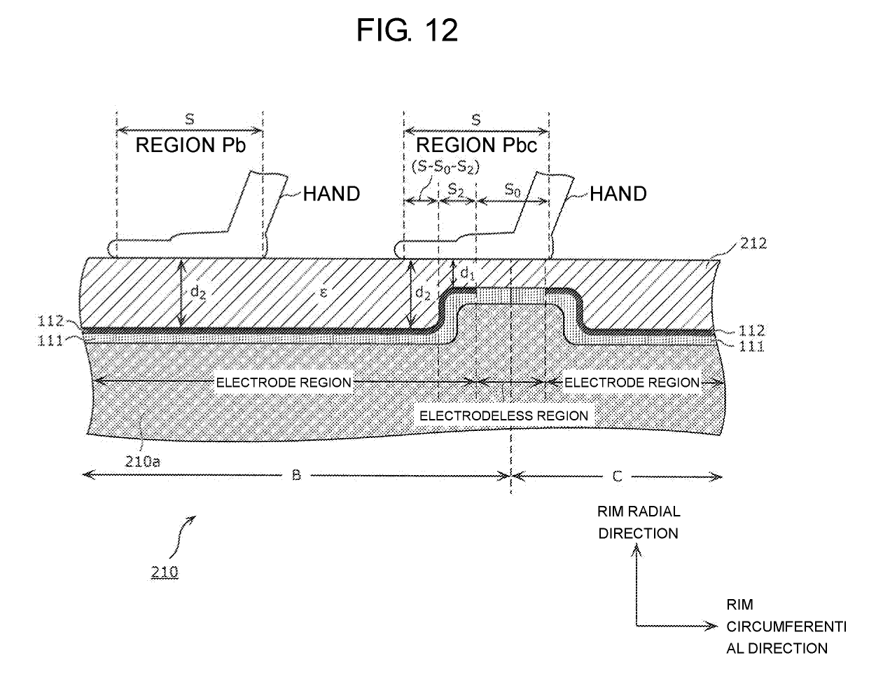

FIG. 12 is a view for explaining thickness d1 and an area of first surface layer portion 212a of surface layer 212 according to the present modification. Note that, as with FIGS. 10 and 11, FIG. 12 is a partial sectional view of rim 210 in a plane along a circumferential direction and a radial direction of rim 210. Further, first surface layer portion 212a and second surface layer portion 212b are not illustrated in FIG. 12. First surface layer portion 212a is a portion having thin thickness d1 of surface layer 212, and second surface layer portion 212b is a portion having thick thickness d2 (>d1) of surface layer 212.

As with the example illustrated in FIG. 10, when a driver's hand touches a portion corresponding to an electrodeless region of a surface of rim 210, it is assumed that detection sensitivity becomes low. Furthermore, when the driver's hand touches a range from one end to another end (the electrodeless region) in the circumferential direction of rim 210 of that portion, it is assumed that detection sensitivity becomes the lowest.

Therefore, as illustrated in FIG. 12, even when the driver's hand touches region Pb near a center of part B located on the surface of rim 210, or even when the driver's hand touches region Pbc including a boundary between part B and part C, it is desirable that the detection sensitivity be substantially equalized by adjusting a thickness of surface layer 212 or the like. Alternatively, it is desirable that the detection sensitivity in region Pbc be higher than the detection sensitivity in region Pb.

Hereinafter, thickness d1 and the area of first surface layer portion 212a will be explained in such a manner that the detection sensitivity in region Pbc is higher than the detection sensitivity in region Pb. As with the example illustrated in FIG. 10, it is assumed herein that a parallel plate capacitor is formed between the driver's hand and sensor wire 112 of sensor 110. Further, it is assumed that the electrodeless region does not contribute to electrostatic capacitance of the capacitor.

When the hand touches region Pb, electrostatic capacitance Cb between the hand and sensor 110 in part B can be expressed by following (formula 5).

Cb=ε₀×ε×S/d₂ (formula 5)

Note that ε is a relative dielectric constant of surface layer 212, and is a common relative dielectric constant of first surface layer portion 212a and second surface layer portion 212b. Further, d₂ is a thickness of second surface layer portion 212b.

On the other hand, when the hand touches region Pbc, electrostatic capacitance Cbc between the hand and sensor 110 in part B can be expressed by following (formula 6).

Cbc=ε₀×ε×S₂/d₁+ε₀×ε×(S−S₀−S₂)/d₂ (formula 6)

Note that d₁ is a thickness of first surface layer portion 212a.

In the present modification as well, it is desirable that the detection sensitivity in region Pbc be higher than the detection sensitivity in region Pb, as described above. In other words, Cbc≥Cb is preferably satisfied. As a result, a relation in (formula 8) is derived by following (formula 7).

{ε₀×ε×S₂/d₁+ε₀×ε×(S−S₀−S₂)/d₂}{ε₀×ε×S/d₂} (formula 7)

S₀≤S₂×(d₂/d₁₂−1) (formula 8)

In other words, when thickness d₂ and area S₀ are determined, thickness d₁ and area S₂ may be determined based on the above-described (formula 8). Further, the area and the width, that is, a circumferential width of rim 210, of first surface layer portion 212a can be derived from these determined area S₂ and area S₀.

Note that in the configuration in FIGS. 11 and 12, sensor wire 112 in the peripheral edge region is substantially parallel to the rim circumferential direction. However, this peripheral edge region may be disposed in rim 210 obliquely and so as to be closer to the outside surface of surface layer 212 than the region other than the peripheral edge region is. With this configuration as well, the detection sensitivity on the outside surface of surface layer 212 can be made uniform.

### (Second Modification)

In the above-described exemplary embodiment, control circuit 120 of electrostatic sensor 100 includes power source circuit 121. However, control circuit 120 may not include power source circuit 121.

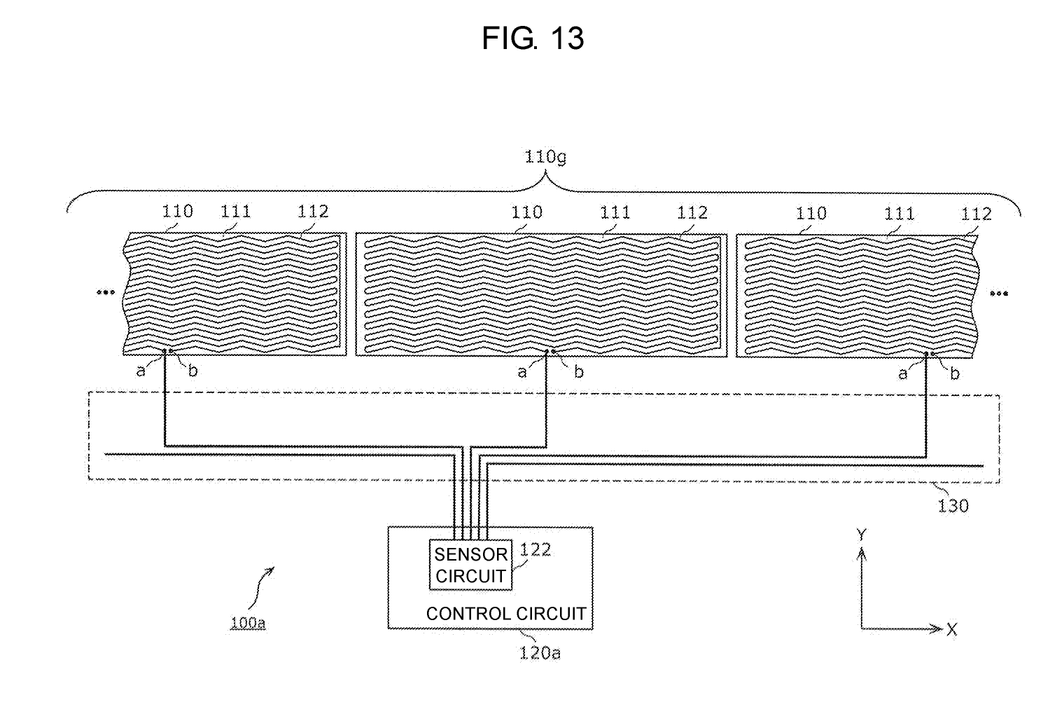

FIG. 13 is a diagram illustrating a detailed configuration example of a portion of an electrostatic sensor according to the present modification.

Electrostatic sensor 100a according to the present modification includes control circuit 120a instead of control circuit 120. Control circuit 120a does not include power source circuit 121.

In this case, electrostatic sensor 100a does not have a function as a heater that heats sensor wire 112 to warm rim 210 of steering wheel 200. However, such electrostatic sensor 100a can exhibit an effect similar to that of the above-described exemplary embodiment.

### (Other Modifications and the Like)

The electrostatic sensors according to one or more aspects have been described above based on the exemplary embodiment and its modifications. However, the present invention is not limited to this exemplary embodiment and its modifications. Configurations in which various variations conceived by those skilled in the art are applied to the exemplary embodiment and its modifications, and configurations established by combining components in different modifications may also fall within the scope of the present invention, without departing from the gist of the present invention.

For example, in the exemplary embodiment and its modifications described above, sensor wire 112 is formed of a metal wire. However, sensor wire 112 may be formed of a metal foil, a conductive sheet, or the like having a substantially constant width. Further, sensor wire 112 may be formed of a material having conductivity, and the material is not limited to metal. A high dielectric constant material for enhancing a dielectric constant of first surface layer portion 212a may be formed of any material as long as the high dielectric constant material has a dielectric constant higher than a dielectric constant of the material of surface layer 212.

In the exemplary embodiment and its modifications described above, sensor wire 112 is formed in the zigzag shape. However, a shape of sensor wire 112 is not limited to that shape, and sensor wire 112 may be formed in any shape.

Further, in the exemplary embodiment and its modifications described above, first surface layer portion 212a covers the peripheral edge regions of sensor wires 112 of two sensors 110. However, two sensors 110 may be integrally formed. In other words, the two peripheral edge regions covered with first surface layer portion 212a may be peripheral edge regions located at both ends of one sensor 110 or sensor wire 112. Even when both the ends of one sensor wire 112 are adjacent to each other on resin layer 210a of rim 210, detection sensitivity may be lowered if there is an electrodeless region between the ends. However, as with the exemplary embodiment and its modifications described above, since the region extending over the ends is covered with first surface layer portion 212a having the high dielectric constant or the thin thickness, lowering of the detection sensitivity can be suppressed.

Further, in the exemplary embodiment and its modifications described above, five sensors 110 included in sensor group 110g have practically the same configuration. However, sensors 110 may have mutually different configurations.

Further, in the exemplary embodiment and its modifications described above, surface layer 212 serving as the example of the cover member covers an upper surface of sensor group 110g. However, the cover member may cover and wrap a whole of sensor group 110g. In other words, sensor group 110g may be embedded in the cover member.

Further, the dielectric constant of first surface layer portion 212a is high in the above-described exemplary embodiment, and the thickness of first surface layer portion 212a is thin in the first modification. However, first surface layer portion 212a may have a higher dielectric constant and a thinner thickness than second surface layer portion 212b. With this configuration, the detection sensitivity at each position of rim 210 can be made more uniform. In other words, distribution of the detection sensitivity in rim 210 can be more flattened.

Further, in the exemplary embodiment and its modifications described above, harness 130 and control circuit 120 are embedded in a lower side of spoke 202 in FIG. 1. However, a configuration of harness 130 and control circuit 120 is not limited to this configuration. Harness 130 and control circuit 120 may be embedded in a right side or a left side of spoke 202. Furthermore, a configuration of harness 130 is not limited to the configuration in which harness 130 is embedded in one place of spoke 202. For example, harnesses 130 of five sensors 110 may be respectively embedded in different places of spoke 202.

### INDUSTRIAL APPLICABILITY

An electrostatic sensor of the present invention has an effect capable of suppressing occurrence of erroneous detection, and is applicable to, for example, a steering wheel or a door handle of a vehicle, a grip of a motorcycle, or a seating sensor of a seat.

1. An electrostatic sensor comprising:
a first sensor electrode and a second sensor electrode disposed adjacent to each other and covered with a cover member; and
a high dielectric constant material configured to make a dielectric constant of a first cover portion included in the cover member higher than a dielectric constant of a second cover portion included in the cover member, the second cover portion being other than the first cover portion in the cover member,
wherein
the first cover portion covers a first peripheral edge region including a peripheral edge located at a position close to the second sensor electrode of the first sensor electrode and a second peripheral edge region including a peripheral edge located at a position close to the first sensor electrode of the second sensor electrode, and
the second cover portion covers a region other than the first peripheral edge region of the first sensor electrode and a region other than the second peripheral edge region of the second sensor electrode.

2. The electrostatic sensor according to claim 1, wherein
at least a portion of the high dielectric constant material is (a) impregnated and disposed in the first cover portion, (b) attached and disposed onto a surface of the first cover portion, or (c) formed of a plurality of particles dispersed and disposed on at least one of the surface and an inside of the first cover portion.

3. The electrostatic sensor according to claim 1, wherein
the cover member is a sheet-shaped base material, and
the first sensor electrode and the second sensor electrode are mounted on a same surface of the base material.

4. An electrostatic sensor comprising a first sensor electrode and a second sensor electrode disposed adjacent to each other and covered with a cover member,
wherein
the first sensor electrode has a first peripheral edge region including a peripheral edge located at a position close to the second sensor electrode and a first center region other than the first peripheral edge region,
the second sensor electrode has a second peripheral edge region including a peripheral edge located at a position close to the first sensor electrode and a second center region included in the cover member, the second center region being other than the second peripheral edge region in the cover member, and
the first peripheral edge region and the second peripheral edge region are closer to an exposed outside surface of the cover member than the first center region and the second center region are.

5. The electrostatic sensor according to claim 4, wherein
the cover member has a first cover portion configured to cover the first peripheral edge region and the second peripheral edge region and a second cover portion configured to cover the first center region and the second center region, and
the first cover portion is thinner than the second cover portion.

6. The electrostatic sensor according to claim 1, wherein
a width of a region including the first peripheral edge region and the second peripheral edge region in a direction in which the first sensor electrode and the second sensor electrode are disposed adjacent to each other is smaller than a width of an object to be detected by the electrostatic sensor in the direction.

7. The electrostatic sensor according to claim 1, wherein
the electrostatic sensor is a grip sensor configured to detect grip of a mounting object, to which the electrostatic sensor is mounted.

8. The electrostatic sensor according to claim 4, wherein
a width of a region including the first peripheral edge region and the second peripheral edge region in a direction in which the first sensor electrode and the second sensor electrode are disposed adjacent to each other is smaller than a width of an object to be detected by the electrostatic sensor in the direction.

9. The electrostatic sensor according to claim 4, wherein
the electrostatic sensor is a grip sensor configured to detect grip of a mounting object, to which the electrostatic sensor is mounted.
